(19) United States
(12) Patent Application Publication
(10) Pub. No.: US 2017/0263528 A1
(43) Pub. Date: Sep. 14, 2017

(54) SEMICONDUCTOR DEVICE

(71) Applicant: Kabushiki Kaisha Toshiba, Minato-ku (JP)

(72) Inventors: Shigeki YOSHIDA, Kawasaki (JP); Kenta KURODA, Suginami (JP)

(73) Assignee: Kabushiki Kaisha Toshiba, Minato-ku (JP)

(21) Appl. No.: 15/393,460

(22) Filed: Dec. 29, 2016

(30) Foreign Application Priority Data
Mar. 9, 2016 (JP) 2016-045305

(51) Int. Cl. H01L 23/373; H01L 29/778; H01L 29/20; H01L 29/205; H01L 29/417; H01L 23/367

(52) U.S. Cl. CPC H01L 23/3735; H01L 29/41758; H01L 23/367; H01L 23/3732; H01L 29/2003; H01L 29/205; H01L 29/7787

(57) ABSTRACT

Certain embodiments provide a semiconductor device of an example including a semiconductor substrate, a semiconductor layer provided on the semiconductor substrate, a drain electrode and source electrode provided on the semiconductor layer, a gate electrode provided between the drain electrode and the source electrode on the semiconductor layer, and a heat transfer unit provided so as to fill a groove which penetrates the semiconductor layer right below the drain electrode till reaches the semiconductor substrate. The heat transfer unit includes a material different from that of the drain electrode and having thermal conductivity higher than that of the semiconductor substrate and the semiconductor layer under an operating temperature of the semiconductor device.

### CROSS REFERENCE TO RELATED APPLICATIONS

This application is based upon and claims the benefit of priority from the prior Japanese Patent Application No.2016-045305 filed in Japan on Mar. 9, 2016; the entire contents of which are incorporated herein by reference.

### FIELD

Embodiments described herein relate generally to a semiconductor device.

### BACKGROUND

In operating a field-effect transistor disposing on a semiconductor substrate a semiconductor such as GaN, GaAs, and the like suitable for high frequency operation, a temperature of the transistor usually increases to a high temperature around 200° C. to 300° C. This is the reason that the field-effect transistor is mainly used as being arranged on a cooling system such as Heatsink and the like.

However, the higher the temperatures of the semiconductor and the semiconductor substrate, the lower thermal conductivity of the semiconductor and that of the semiconductor substrate on which the semiconductor is formed. Therefore, the thermal conductivity of the semiconductor substrate and the semiconductor is low when the transistor is operated and its temperature becomes high. As a result, even though the transistor is arranged on the cooling system, heat of the transistor may not be radiated sufficiently.

### BRIEF DESCRIPTION OF THE DRAWINGS

FIG. 1A is a schematic top view illustrating a semiconductor device 10 according to a first embodiment;

FIG. 1B is a partial cross-sectional view illustrating an enlarged cross-section of the semiconductor device 10 taken a dashed-dotted line X-X′ in FIG. 1A;

FIG. 2A is an enlarged top view of the semiconductor device 10 according to the first embodiment;

FIG. 2B is a cross-sectional view of the semiconductor device 10 taken a dashed-dotted line Y-Y′ in FIG. 2A;

FIG. 3A is a top view illustrating a semiconductor device 10 according to a second embodiment corresponding to FIG. 2A;

FIG. 3B is a cross-sectional view of the semiconductor device 10 taken a dashed-dotted line Y-Y′ in FIG. 3A;

FIG. 4 is a cross-sectional view illustrating a semiconductor device 10 according to a third embodiment corresponding to FIG. 3B;

FIG. 5A is a top view illustrating a semiconductor device 10 according to a fourth embodiment corresponding to FIG. 3A;

FIG. 5B is a cross-sectional view of the semiconductor device 10 taken a dashed-dotted line Y-Y′ in FIG. 5A; and

FIG. 6 is a cross-sectional view illustrating a semiconductor device 10 according to a fifth embodiment corresponding to FIG. 5B.

### DETAILED DESCRIPTION

A semiconductor device of an example includes a semiconductor substrate, a semiconductor layer provided on the semiconductor substrate, a drain electrode and source electrode provided on the semiconductor layer, a gate electrode provided between the drain electrode and the source electrode on the semiconductor layer, and a heat transfer unit provided so as to fill a groove which penetrates the semiconductor layer right below the drain electrode and reaches the semiconductor substrate. The heat transfer unit includes a material different from that of the drain electrode and having thermal conductivity higher than that of the semiconductor substrate and the semiconductor layer under an operating temperature of the semiconductor device.

A semiconductor device of another example includes a semiconductor substrate, a semiconductor layer provided on the semiconductor substrate, a pad provided on the semiconductor layer, and a heat transfer unit provided so as to fill a groove which penetrates the semiconductor layer right below the pad and reaches the semiconductor substrate. The heat transfer unit includes a material different from that of the pad and having thermal conductivity higher than that of the semiconductor substrate and the semiconductor layer under the operating temperature of the semiconductor device.

Hereinafter, the semiconductor device according to embodiments will be described in detail with reference to the accompanying drawings.

### First Embodiment

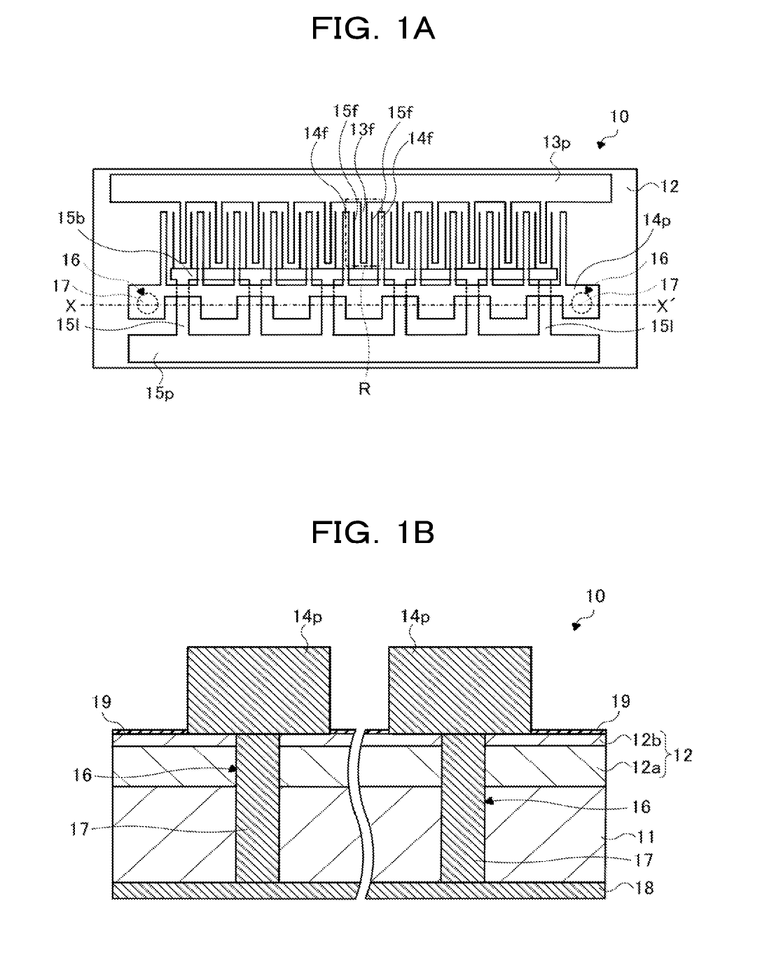

FIG. 1A is a schematic top view illustrating a semiconductor device 10 according to the present embodiment. FIG. 1B is a partial cross-sectional view illustrating an enlarged cross-section of the semiconductor device 10 taken a dashed-dotted line X-X′ in FIG. 1A. Hereinafter, the semiconductor device 10 according to the first embodiment will be described with reference to FIGS. 1A and 1B. Note that an insulation film is omitted in FIG. 1A.

As illustrated in FIG. 1A, the semiconductor device 10 according to the present embodiment includes a plurality of field-effect transistors arranged in parallel on a semiconductor substrate 11 (FIG. 1B). A semiconductor layer 12 is provided on the semiconductor substrate 11 (FIG. 1B). On a top surface of the semiconductor layer 12, a plurality of finger-shaped drain electrodes 13f, a plurality of finger-shaped source electrodes 14f, and a plurality of finger-shaped gate electrodes 15f are mutually arrange in parallel.

The plurality of drain electrodes 13f is connected to a drain pad 13p provided on the top surface of the semiconductor layer 12. Similarly, the plurality of source electrodes 14f is connected to a source pad 14p provided on the top surface of the semiconductor layer 12. The plurality of gate electrodes 15f is connected to a gate bus line 15b provided on the top surface of the semiconductor layer 12. The gate bus line 15b is coupled to a gate pad 15p provided on the top surface of the semiconductor layer 12 through a plurality of lead lines 15l provided on the top surface of the semiconductor layer 12.

As illustrated in FIG. 1B, the semiconductor layer 12 right below the source pad 14p and the semiconductor substrate 11 are provided with through holes 16 penetrating the same. Each through hole 16 is filled with a conductor 17. The conductor 17 electrically connects the source pad 14p and an undersurface electrode 18 provided throughout an undersurface of the semiconductor substrate 11. Accordingly, each source electrode 14f has a potential identical to that of the undersurface electrode 18. The semiconductor device 10 is mainly used as grounding the undersurface electrode 18. In such a case, for example, each source electrode 14f has a ground potential.

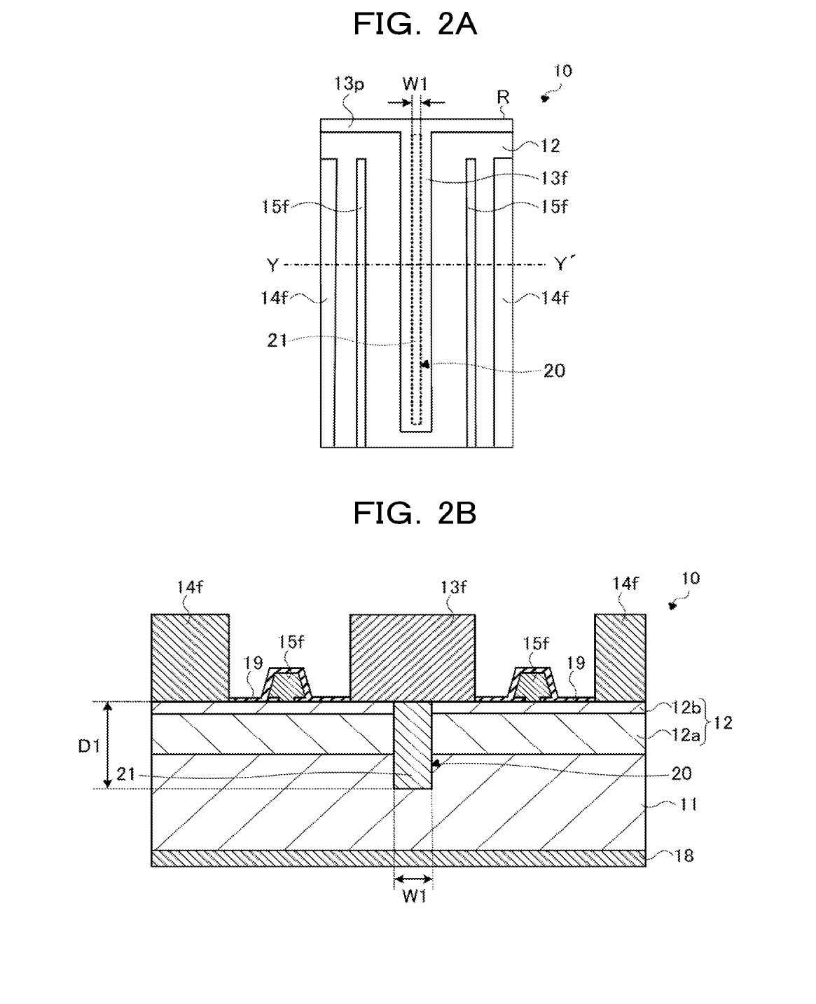

FIG. 2A is an enlarged top view of the semiconductor device 10 according to the present embodiment. Specifically, FIG. 2A illustrates an enlarged region R illustrated in FIG. 1A. The region R includes two field-effect transistors arranged in parallel. FIG. 2B is a cross-sectional view of the semiconductor device 10 taken a dashed-dotted line Y-Y′ in FIG. 2A. Hereinafter, each field-effect transistors according to the present embodiment will be described with reference to FIGS. 2A and 2B. Note that the insulation film is omitted in FIG. 2A.

As illustrated in FIG. 2B, an electron transit layer 12a and an electron supply layer 12b are laminated in the order mentioned on the top surface of the semiconductor substrate 11. In the present embodiment, for example, the semiconductor substrate 11 is a SiC substrate and the electron transit layer 12a includes GaN. The electron supply layer 12b includes AlGaN. Hereinafter, note that the electron transit layer 12a and the electron supply layer 12b are collectively referred to as the semiconductor layer 12. The semiconductor layer 12 may also include a layer other than the above-mentioned layers. For example, a buffer layer may be provided between the semiconductor substrate 11 and the electron transit layer 12a. In such a case, the semiconductor layer 12 may also include the buffer layer.

The finger-shaped drain electrodes 13f are provided on the top surface of the semiconductor layer 12. Furthermore, the finger-shaped source electrodes 14f are provided at positions apart from the drain electrodes 13f on the top surface of the semiconductor layer 12. These electrodes 13f and 14f are brought into contact with the semiconductor layer 12 by an ohmic contact. In a case where the semiconductor layer 12 includes a compound semiconductor of GaN type as mentioned above, the drain electrodes 13f and the source electrodes 14f both include a metal laminating, for example, Ti and Al in the order mentioned. In regard to the drain pad 13p (FIG. 1A) to which the plurality of drain electrodes 13f is connected and the source pad 14p (FIG. 1A) to which the plurality of source electrodes 14f is connected, both of them also include the metal laminating, for example, Ti and Al in the order mentioned. Note that the conductor 17 (FIG. 1B) and the undersurface electrode 18 (FIG. 1B) electrically connected to the source pad 14p include, for example, Au.

On the top surface of the semiconductor layer 12, each finger-shaped gate electrode 15f is provided between each drain electrode 13f and source electrode 14f so as to contact with neither drain electrode 13f nor source electrode 14f. The gate electrodes 15f is brought into contact with the semiconductor layer 12 by a Schottky junction. In a case where the semiconductor layer 12 includes the compound semiconductor of the GaN type as mentioned above, the gate electrodes 15f includes a metal laminating, for example, Ni and Au in the order mentioned. The gate bus line 15b to which the plurality of gate electrodes 15f is connected, the plurality of lead lines 15l, and the gate pad 15p also includes the metal laminating, for example, Ni and Au in the order mentioned.

Furthermore, an insulation film 19 is provided between each drain electrode 13f and source electrode 14f on the top surface of the semiconductor layer 12 so as to cover each gate electrode 15f. The insulation film 19 is a so-called passivation film. The insulation film 19 may also be provided so as to cover a region other than the semiconductor layer 12. The insulation film 19 includes, for example, SiN or SiO2.

In such field-effect transistors, a belt-like groove 20 is provided in the semiconductor layer 12 right below each finger-shaped drain electrode 13f and the semiconductor substrate 11. The belt-like groove 20 is provided along a longitudinal direction of each drain electrode 13f. The groove 20 has a width W1 narrower than that of each drain electrode 13f in a width direction (a direction perpendicular to the longitudinal direction) of each drain electrode 13f. Furthermore, the groove 20 has a depth D1 deep enough to penetrate at least the semiconductor layer 12 till it reaches the semiconductor substrate 11. The depth D1 of the groove 20 may be equal to at least a thickness of the semiconductor layer 12. However, as illustrated in the drawing, it is preferable that the depth D1 is deep enough to enter into the semiconductor substrate 11.

Inside the groove 20, a heat transfer unit 21 is provided so as to fill the groove 20. As a result, the heat transfer unit 21 has a shape identical to that of the groove 20. The heat transfer unit 21 includes a material different from that of the drain electrodes 13f . The material included in the heat transfer unit 21 has thermal conductivity higher than that of the semiconductor substrate 11 and semiconductor layer 12 under an operating temperature of each field-effect transistor.

For example, under the operating temperature of each field-effect transistor (around 200° C. to 330° C.), thermal conductivity of SiC is 160-230 W/m-K, and thermal conductivity of GaN, AlGaN is 60-80 W/m-K. On the contrary, thermal conductivity of Cu under the operating temperature is 385-395 W/m-K, thermal conductivity of Au is 300-310 W/m-K, and thermal conductivity of a diamond formed by CVD is 900-1000 W/m-K. Therefore, the heat transfer unit 21 includes, for example, any one of Cu, Au, and the diamond formed by CVD.

Note that thermal conductivity of Si under the operating temperature is 70-90 W/m-K, while thermal conductivity of GaAs is 20-25 W/m-K. Therefore, even in a case where the semiconductor device 10 is made as a silicon-type field-effect transistor or a GaAs-type field-effect transistor, the heat transfer unit 21 can be configured to include, for example, any one of Cu, Au, and the diamond formed by CVD.

For example, such a semiconductor device 10 can be manufactured as follows. First, the semiconductor layer 12 is formed on the semiconductor substrate 11. Then, the groove 20 is formed at a position where it may be right below each drain electrode 13f. Furthermore, the through holes 16 are formed at positions where it may be right below the source pad 14p. Next, each through hole 16 is filled with the desired conductor 17 and the groove 20 is filled with a desired material . Lastly, the various types of electrodes and the like 13f, 13p, 14f, 14p, 15f, 15b, 15l, 15p and the insulation film 19 are formed on the top surface of the semiconductor layer 12. The semiconductor device 10 can be manufactured in such manners.

According to the above-mentioned first embodiment, provided right below the drain electrodes 13f is the heat transfer unit 21 including the material having the thermal conductivity higher than that of the semiconductor substrate 11 and semiconductor layer 12 under an operating temperature of the semiconductor device 10. Therefore, it is possible to provide the semiconductor device 10 with excellent radiatability.

### Second Embodiment

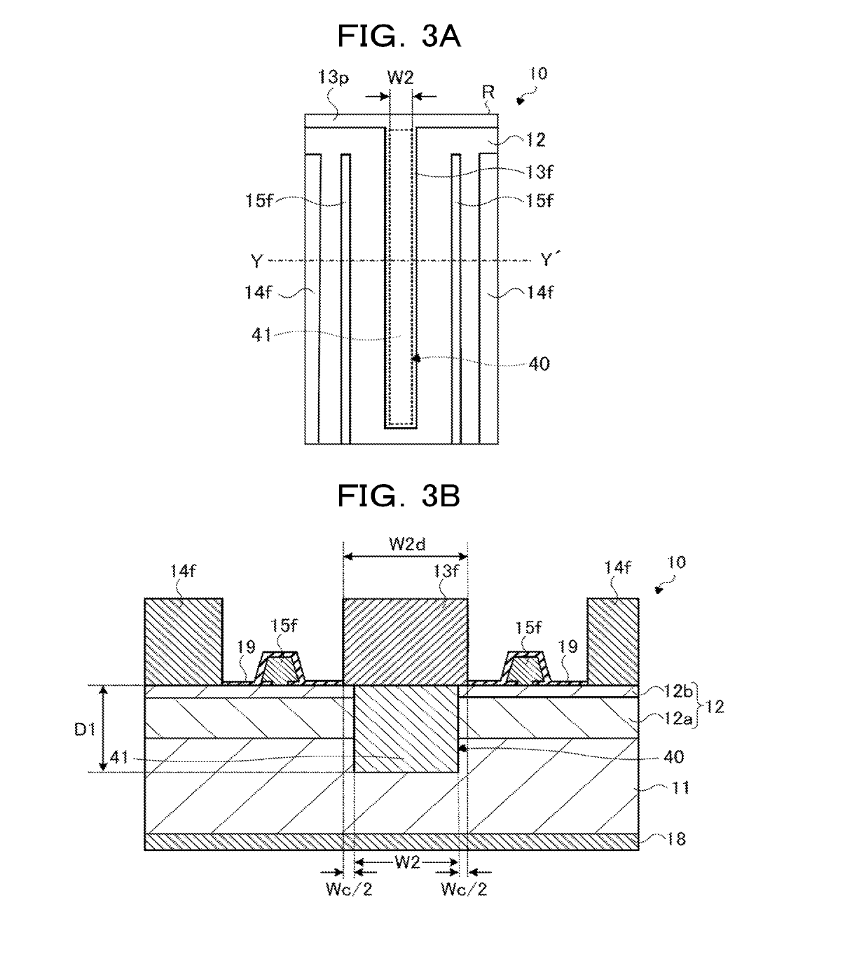

FIG. 3A is a top view illustrating a semiconductor device 10 according to a second embodiment corresponding to FIG. 2A. FIG. 3B is a cross-sectional view of the semiconductor device 10 taken a dashed-dotted line Y-Y′ in FIG. 3A. Hereinafter, the semiconductor device 10 according to the second embodiment will be described with reference to FIGS. 3A and 3B. Hereinafter, the same members as in the first embodiment will be denoted with the same symbols and explanations thereof will be omitted.

The semiconductor device 10 according to the second embodiment is provided with a groove 40 to which a heat transfer unit 41 is provided. The groove 40 has a width different from that of the groove 20 provided in the semiconductor device 10 according to the first embodiment. As illustrated in FIG. 3A and FIG. 3B, in the semiconductor device 10 according to the second embodiment, a width W2 of the groove 40 provided right below each drain electrode 13f is wider than the width W1 (FIG. 2A, FIG. 2B) of the groove 20 provided in the semiconductor device 10 according to the first embodiment. The width W2 of the groove 40 is substantially equal to a width of each drain electrode 13f.

The semiconductor layer 12 applies a current to the drain electrodes 13f so that at least a part of the drain electrodes 13f is necessarily brought into contact with the semiconductor layer 12. Herein, the width W2 of the groove 40 substantially equal to the width of each drain electrode 13f is a width (W2d−Wc) subtracting a contact width (Wc) between each drain electrode 13f and the semiconductor layer 12 from the width (W2d) of each drain electrode 13f. The contact width (Wc) is a minimum necessary width for the current to flow from the semiconductor layer 12 to the drain electrodes 13f.

The heat transfer unit 41 is provided so as to fill the groove 40 having the width W2. As a result, the heat transfer unit 41 has a shape identical to the groove 40. The heat transfer unit 41 includes a material different from a material included in each drain electrode 13f. The material included in the heat transfer unit 41 has thermal conductivity higher than that of the semiconductor substrate 11 and the semiconductor layer 12 under an operating temperature of each field-effect transistor.

Such a semiconductor device 10 can be manufactured in a manner similar to the semiconductor device 10 according to the first embodiment.

In the above-mentioned second embodiment, it is possible to provide the semiconductor device 10 with excellent radiatability due to a reason similar to the first embodiment.

Furthermore, according to the second embodiment, a width of the heat transfer unit 41 is wide, compared to the first embodiment. Therefore, it is possible to provide the semiconductor device 10 with more excellent radiatability.

### Third Embodiment

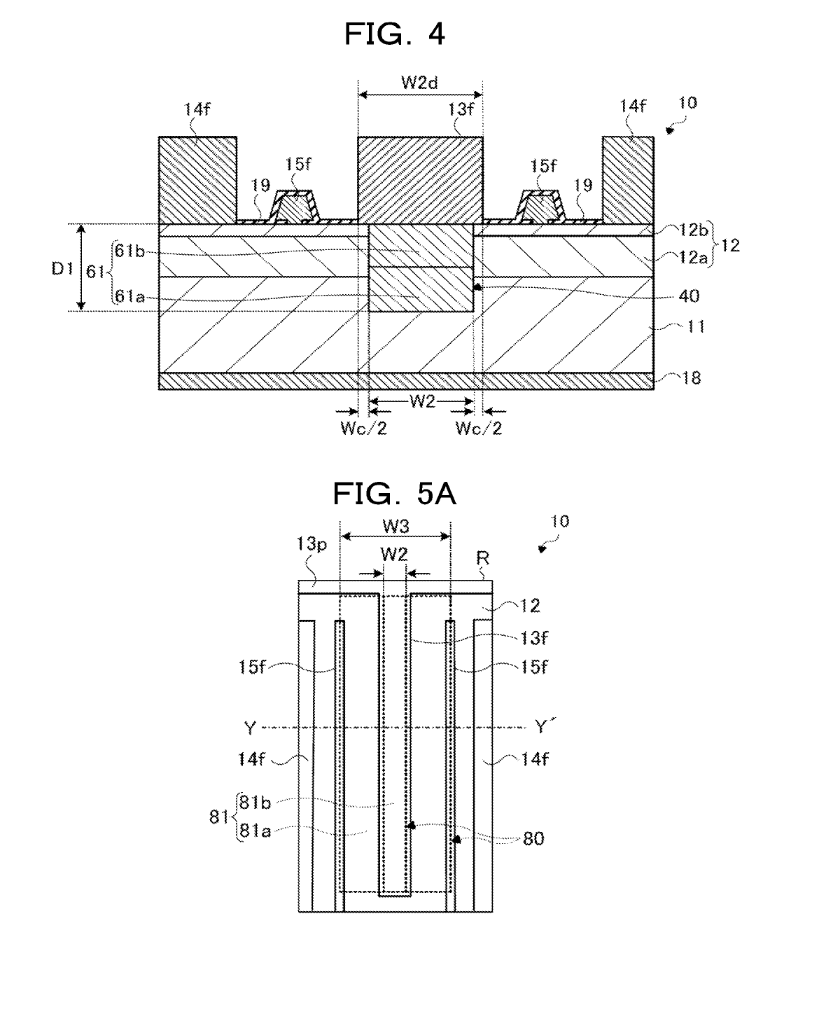

FIG. 4 is a cross-sectional view illustrating a semiconductor device 10 according to a third embodiment corresponding to FIG. 3B. Hereinafter, the semiconductor device 10 according to the third embodiment will be described with reference to FIG. 4. Note that a top view of the semiconductor device 10 according to the third embodiment is similar to that of the semiconductor device 10 according the second embodiment. Therefore, the top view of the semiconductor device 10 according to the third embodiment will be omitted. Hereinafter, the same members as in the second embodiment will be denoted with the same symbols and explanations thereof will be omitted.

A heat transfer unit 61 included in the semiconductor device 10 according to the third embodiment has a configuration different from the heat transfer unit 41 of the semiconductor device 10 according to the second embodiment. As illustrated in FIG. 4, in the semiconductor device 10 according to the third embodiment, the heat transfer unit 61 includes two layers, that is, heat transfer layers 61a and 61b, each having a material different from each other. Each of the heat transfer layers 61a and 61b includes a material different from that of each drain electrode 13f. The material included in each of the heat transfer layers 61a and 61b has thermal conductivity higher than that of the semiconductor substrate 11 and the semiconductor layer 12 under an operating temperature of each field-effect transistor. Note that the heat transfer layer 61b close to each drain electrode 13f, a heat source, preferably includes a material having thermal conductivity higher than that of the material included in the heat transfer layer 61a. For example, in the present embodiment, in a case where the undersurface heat transfer layer 61a includes Au or Cu, it is preferable that the upper surface heat transfer layer 61b includes the diamond formed by CVD.

Note that the heat transfer unit 61 may also include two or more heat transfer layers. A heat transfer layer closer to each drain electrodes 13f which is the heat source preferably includes a material having higher thermal conductivity.

Such a semiconductor device 10 can be manufactured in a manner similar to the semiconductor device 10 according to the second embodiment.

In the above-mentioned third embodiment, it is possible to provide the semiconductor device 10 with excellent radiatability due to a reason similar to the second embodiment.

Furthermore, according to the third embodiment, the heat transfer unit 61 includes a plurality of heat transfer layers 61a, 61b. Therefore, it is possible to prevent increase in drain-source inter-electrode parasitic capacitance Cds comparing to a case in which the heat transfer unit 61 is formed by one type of a metal such as Au or Cu.

### Fourth Embodiment

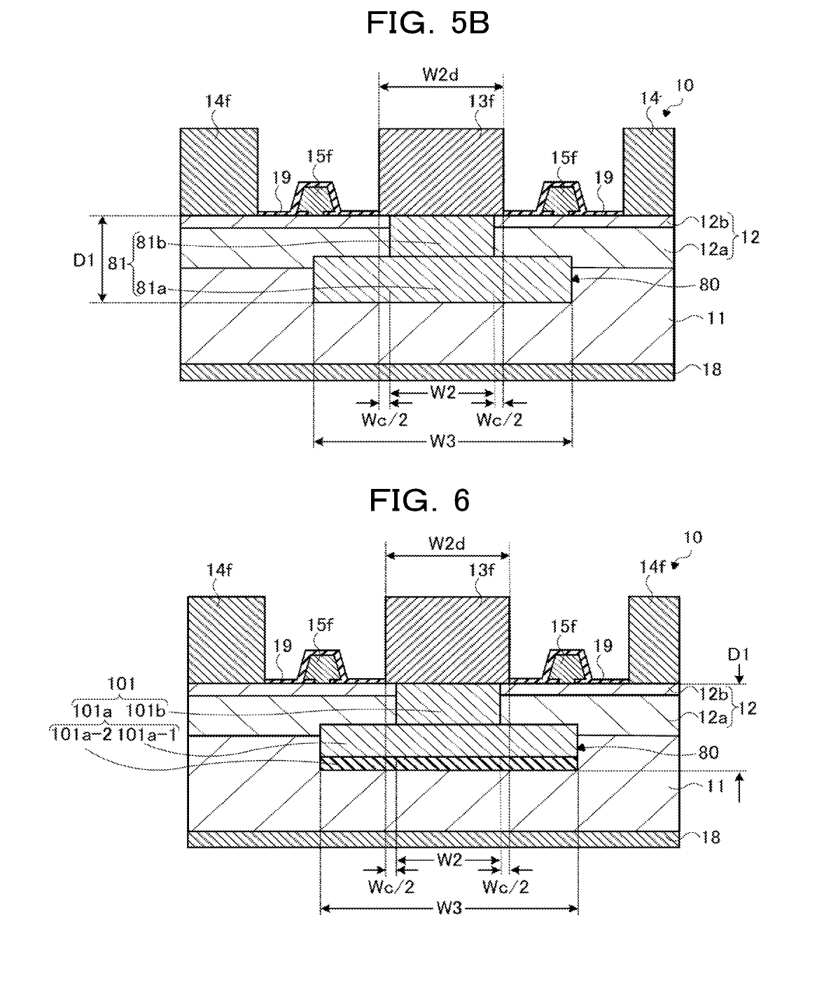

FIG. 5A is a top view illustrating a semiconductor device 10 according to a fourth embodiment corresponding to FIG. 3A. FIG. 5B is a cross-sectional view of the semiconductor device 10 taken a dashed-dotted line Y-Y′ in FIG. 5A. Hereinafter, the semiconductor device 10 according to the fourth embodiment will be described with reference to FIGS. 5A and 5B. Hereinafter, the same members as in the third embodiment will be denoted with the same symbols and explanations thereof will be omitted.

Compared to the semiconductor device 10 according to the third embodiment, the semiconductor device 10 according to the fourth embodiment is different in that a width W3 of a bottom part of a groove 80 is made wider than a width W2 of an upper part of the groove 80. In other words, in the semiconductor device 10 according to the fourth embodiment, the groove 80 has a shape spreading stepwise as being apart from each drain electrode 13f.

Therefore, compared to the semiconductor device 10 according to the third embodiment, the semiconductor device 10 according to the fourth embodiment is different in that a heat transfer unit 81 is configured to include an undersurface heat transfer layer 81a having the width W3 and an upper surface heat transfer layer 81b having the width W2. In other words, in the semiconductor device 10 according to the fourth embodiment, a heat transfer unit 81 spreads stepwise as being apart from each drain electrode 13f.

Such a semiconductor device 10 can be manufactured in a manner similar to the semiconductor device 10 according to the third embodiment.

In the above-mentioned fourth embodiment, due to a reason similar to the third embodiment, it is possible to provide the semiconductor device 10 with excellent radiatability and less increase in drain-source inter-electrode parasitic capacitance Cds.

Note that it is possible to prevent increase in parasitic capacitance between each gate electrode 15f and the undersurface heat transfer layer 81a (gate-drain inter-electrode parasitic capacitance) by allowing the undersurface heat transfer layer 81a to include a material other than metals.

Furthermore, according to the fourth embodiment, the width W3 of the undersurface heat transfer layer 81a of the heat transfer unit 81 is made wider than the width W2 of the upper surface heat transfer layer 81b of the heat transfer unit 81. As a result, compared to the semiconductor device 10 according to the third embodiment, it is possible to further improve the radiatability of the semiconductor device 10.

### Fifth Embodiment

FIG. 6 is a cross-sectional view illustrating a semiconductor device 10 according to a fifth embodiment corresponding to FIG. 5B. Hereinafter, the semiconductor device 10 according to the fifth embodiment will be described with reference to FIG. 6. Note that a top view of the semiconductor device 10 according to the fifth embodiment is similar to the semiconductor device 10 according the fourth embodiment. Therefore, the top view of the semiconductor device 10 according to the fifth embodiment will be omitted. Hereinafter, the same members as in the fourth embodiment will be denoted with the same symbols and explanations thereof will be omitted.

The semiconductor device 10 according to the fifth embodiment includes an upper surface heat transfer layer 101b and an undersurface heat transfer layer 101a. Compared to the semiconductor device 10 according to the fourth embodiment, the upper surface heat transfer layer 101b has a configuration similar to that of the upper surface heat transfer layer 81b, while the undersurface heat transfer layer 101a has a configuration different from that of the undersurface heat transfer layer 81a. The undersurface heat transfer layer 101a includes a first undersurface heat transfer layer 101a-1 and a second undersurface heat transfer layer 101a-2. The configuration of the first undersurface heat transfer layer 101a-1 is similar to that of the undersurface heat transfer layer 81a in the semiconductor device 10 according to the fourth embodiment. The second undersurface heat transfer layer 101a-2 includes an insulation film having thermal conductivity higher than that of the semiconductor substrate 11 and the semiconductor layer 12 under an operating temperature of the semiconductor device 10. As illustrated in FIG. 6, the undersurface heat transfer layer 101a is configured so as to laminate the first undersurface heat transfer layer 101a-1 on the second undersurface heat transfer layer 101a-2. In other words, a layer farthest from each drain electrode 13f (the second undersurface heat transfer layer 101a-2) within a heat transfer unit 101 is the insulation film. The second undersurface heat transfer layer 101a-2 includes, for example, the diamond formed by CVD.

Such a semiconductor device 10 can be manufactured in a manner similar to the semiconductor device 10 according to the fourth embodiment.

In the above-mentioned fifth embodiment, due to a reason similar to the fourth embodiment, it is possible to provide the semiconductor device 10 with excellent radiatability and less increase in drain-source inter-electrode parasitic capacitance Cds.

Similar to the fourth embodiment, the undersurface heat transfer layer 101a preferably includes a material other than metals.

Furthermore, according to the fifth embodiment, a part of the undersurface heat transfer layer 101a of the heat transfer unit 101 (the second undersurface heat transfer layer 101a-2) includes the insulation film. Therefore, parasitic capacitance C5 between the first undersurface heat transfer layer 101a-1 and the undersurface electrode 18 can be made smaller than parasitic capacitance C4 between the undersurface heat transfer layer 81a and the undersurface electrode 18 of the semiconductor device 10 according to the fourth embodiment. As a result, it is possible to further improve performance of the semiconductor device 10.

The embodiments of the present invention have been described above. However, these embodiments are examples and the present invention should not be restricted to these embodiments. Novel embodiments relating to these embodiments are practicable in other various embodiments and can be omitted, substituted, or modified within the scope of the gist of the present invention. Such embodiments and modifications thereof are involved within the invention described in the claims and a range equivalent thereto as well as within the scope and gist of the present invention.

In each of the above-mentioned embodiments, the heat transfer units 21, 41, 61, 81, 101 are provided right below each drain electrode 13f. However, for example, the heat transfer units 21, 41, 61, 81, 101 may be provided right below the drain pad 13p. Furthermore, the heat transfer units 21, 41, 61, 81, 101 may be provided right below the source pad 14p, gate bus lines 15b, lead lines 15l, and gate pad 15p where the source electrodes 14f and through holes 16 are not provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and sprit of the inventions.

What is claimed is:

1. A semiconductor device, comprising:
a semiconductor substrate;
a semiconductor layer provided on the semiconductor substrate;
a drain electrode and a source electrode provided on the semiconductor layer;
a gate electrode provided between the drain electrode and the source electrode on the semiconductor layer; and
a heat transfer unit provided so as to fill a groove penetrating the semiconductor layer right below the drain electrode and reaching the semiconductor substrate, wherein
the heat transfer unit includes a material different from a material of the drain electrode and having thermal conductivity higher than thermal conductivity of the semiconductor substrate and the semiconductor layer under an operating temperature of the semiconductor device.

2. The semiconductor device according to claim 1, wherein
a width of the heat transfer unit is substantially equal to a width of the drain electrode.

3. The semiconductor device according to claim 1, wherein
the heat transfer unit is provided with a plurality of heat transfer layers each having a material different from each other, and
a layer closer to the drain electrode among the plurality of heat transfer layers includes a material having higher thermal conductivity.

4. The semiconductor device according to claim 1, wherein
the heat transfer unit is provided with a plurality of heat transfer layers each having a material different from each other, and
a layer farther from the drain electrode among the plurality of heat transfer layers has a wider width.

5. The semiconductor device according to claim 1, wherein
the heat transfer unit is provided with a plurality of heat transfer layers each having a material different from each other, and
a layer farthest from the drain electrode among the plurality of heat transfer layers is an insulation layer.

6. The semiconductor device according to claim 1, wherein
the heat transfer unit is provided so as to fill the groove penetrating the semiconductor layer right below the drain electrode and entering into the semiconductor substrate.

7. The semiconductor device according to claim 5, wherein
the insulation layer is an insulation film including a diamond.

8. The semiconductor device according to claim 1, wherein
the semiconductor substrate is a SiC substrate,
the semiconductor layer includes a GaN layer and an AlGaN layer, and
the heat transfer unit includes any one of Cu, Au, and a diamond.

9. The semiconductor device according to claim 3, wherein
the heat transfer unit is provided with an upper surface heat transfer layer and an undersurface heat transfer layer,
the upper surface heat transfer layer including a diamond, and
the undersurface heat transfer layer including Au or Cu.

10. A semiconductor device, comprising:
a semiconductor substrate;
a semiconductor layer provided on the semiconductor substrate;
a pad provided on the semiconductor layer; and
a heat transfer unit provided so as to fill a groove penetrating the semiconductor layer right below the pad and reaching the semiconductor substrate, wherein
the heat transfer unit includes a material different from a material of the pad and having thermal conductivity higher than thermal conductivity of the semiconductor substrate and the semiconductor layer under an operating temperature of the semiconductor device.

11. The semiconductor device according to claim 10, wherein
the pad is a drain pad connected to a drain electrode.

12. The semiconductor device according to claim 10, wherein
the pad is a gate pad connected to a gate electrode.

13. The semiconductor device according to claim 10, wherein
the pad is a source pad connected to a source electrode.

14. The semiconductor device according to claim 10, wherein
the heat transfer unit is provided with a plurality of heat transfer layers each including a material different from each other, and
a layer closer to the pad among the plurality of heat transfer layers includes a material having higher thermal conductivity.

15. The semiconductor device according to claim 10, wherein
the heat transfer unit is provided with a plurality of heat transfer layers each including a material different from each other, and
a layer farther from the pad among the plurality of heat transfer layers has a wider width.

16. The semiconductor device according to claim 10, wherein
the heat transfer unit is provided with a plurality of heat transfer layers each including a material different from each other, and
a layer farthest from the pad among the plurality of heat transfer layers is an insulation layer.

17. The semiconductor device according to claim 10, wherein
the heat transfer unit is provided so as to fill the groove penetrating the semiconductor layer right below the pad and entering into the semiconductor substrate.
